(19) United States
(12) Patent Application Publication
(10) Pub. No.: US 2004/0266066 A1
(43) Pub. Date: Dec. 30, 2004

(54) Bump structure of a semiconductor wafer and manufacturing method thereof

(75) Inventor: Tong Hong Wang, Kaohsiung City (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/874,239

(22) Filed: Jun. 24, 2004

(30) Foreign Application Priority Data
Jun. 30, 2003 (TW) 092117874

(51) Int. Cl. H01L 21/44

(52) U.S. Cl. 438/123

(57) ABSTRACT

A bump structure is applicable for disposing above a semiconductor wafer, which has a plurality of bonding pads and a passivation exposing the bonding pads on which a plurality of patterned under bump metallurgy layers are formed. It is characterized that the bump structure is made of a first bump and a second bump, and the bump structure is disposed on one of the patterned under bump metallurgy layer wherein the second bump covers the first bump and the melting point of the second bump is below the melting point of the first bump. In addition, a manufacturing method of the bump structure is provided.

### FIELD OF INVENTION

This invention relates to a bump structure of a semiconductor wafer. More particularly, the present invention is related to a bump structure applicable to be utilized in a semiconductor wafer to increase the height of the bump structure and prevent the bump structure from being collapsed when said wafer is singulated into individual chips and said chips are mounted to substrates. Moreover, this invention also provides a manufacturing method of the bump structure of the semiconductor wafer as mentioned above.

### RELATED ART

In this information explosion age, integrated circuits products are used almost everywhere in our daily life. As fabricating technique continue to improve, electronic products having powerful functions, personalized performance and a higher degree of complexity are produced. Nowadays, most electronic products are relatively light and have a compact body. Hence, in semiconductor production, various types of high-density semiconductor packages, for example ball grid array package (BGA), chip-scale package (CSP), multi-chips module package (MCM) and flip chip package (F/C), have been developed.

However, as mentioned above, flip chip is one of the most commonly used techniques for forming an integrated circuits package. Compared with a wire-bonding package or a tape automated bonding (TAB) package, a flip-chip package has a shorter electrical path on average and has a better overall electrical performance. In said flip-chip package, the bonding pads on a chip and the contacts on a substrate are connected together through a plurality of bumps formed by the method of bumping process. It should be noted that there is further an under bump metallurgy layer disposed on the bonding pads of the chip to be regarded as a connection medium for connecting to the bumps and enhancing the mechanical strength of the connection of the chip to the substrate after said chip is attached to the substrate.

Referring to FIG. 1, it shows a conventional bump structure of a semiconductor wafer. The semiconductor wafer 100 mainly comprises a passivation layer 102, a plurality of bonding pads 104 and a plurality of patterned under bump metallurgy layers 106 formed on the bonding pads 104 (only one bonding pad with n patterned under bump metallurgy layer thereon is shown), wherein the patterned under bump metallurgy layer 106 located over the bonding pad 104 partially covers the passivation layer 102. Moreover, a plurality of bumps are transformed into bump structures 108 to be attached to the patterned under bump metallurgy layers 106 after a reflow process is performed. Afterwards, said wafer 100 having the bump structures 108 formed thereon is singulated into a plurality of chips having the bump structures 108 for flip-chip bonding to substrates to form flip-chip packages. Generally speaking, each of the patterned under bump metallurgy layers 106 mainly comprises an adhesive layer, a barrier layer and a wetting layer. The adhesive layer is utilized to enhance the mechanical strength of the connection of the bonding pad 104 to the barrier layer, wherein the material of the adhesive layer is made of aluminum or titanium. The barrier layer is utilized to avoid the diffusion of the underlying metal, wherein the material of the barrier layer usually includes nickel-vanadium alloy, nickel-copper alloy and nickel. In addition, the wetting layer, for example a copper layer, is utilized to enhance the wettability of the bump structures with the under bump metallurgy layer 106. It should be noted that the patterned under bump metallurgy layer 106 is formed through conventional bumping processes, such as the processes of placing a photo-resist layer, proceeding plating or sputtering metal on the surface of the semiconductor wafer 100 and etching the metal through the photo-resist layer.

As mentioned above, when each singulated chip with bump structures is mounted to the corresponding substrate in a flip-chip manner and another reflow process is performed to securely fix the bump structure to an upper surface of the substrate, the height of the bump structure will become smaller, such as the height of H between the upper substrate and the active surface of the chip is transformed into the height of h due to the effect of gravity and the weight of the chip. Therein, the ratio of h over H is usually ranged from about 0.7 to about 0.75. Moreover, when the pitch of the bonding pads is smaller due to more and more bonding pads formed in a semiconductor wafer, the height of each bump structure will become smaller and smaller. Accordingly, the shear force at the attachment of the bump structure to the corresponding substrate will become larger so as to lower the mechanical reliability of the semiconductor package.

Therefore, providing another bump structure and manufacturing method thereof to solve the mentioned-above disadvantages is the most important task in this invention.

### SUMMARY OF THE INVENTION

In view of the above-mentioned problems, an objective of this invention is to provide a bump structure applicable to be utilized in a semiconductor wafer to increase the height of the bump structure and prevent the bump structure from being collapsed when said wafer is singulated into individual chips and said chips are mounted to substrates.

To achieve these and other advantages and in accordance with the purpose of the invention, as embodied and broadly described herein, the invention provides bump structures formed on patterned under bump metallurgy layers and located over the bonding pads respectively. Therein, each of the bump structures mainly comprises a first bump with a first melting point and a second bump with a second melting point lower than the first melting point of the first bump, and the second bump covers the first bump. Besides, when the bump structure is melted to shape into a sphere or a ball-like shape under the step of reflowing, the reflowing temperature is controlled to be between the melting point of the first bump and that of the second bump. Moreover, the reflowing process performed to have the bump structure securely fixed to the corresponding substrate is also under a reflowing temperature between the melting point of the first bump and that of the second bump.

In addition, this invention also provides a manufacturing method of the above-mentioned bump structures. Therein, the manufacturing method mainly comprises the following steps. Firstly, a semiconductor wafer having a passivation layer and a plurality of bonding pads wherein said passivation layer exposes the bonding pads and there is further an under bump metallurgy layer formed on the bonding pads. Next, a plurality of first bumps with a first melting point are formed on the under bump metallurgy layer and located over the bonding pads respectively. Then, a plurality of second bumps with a second melting point lower than the first melting point of the first bumps covers the corresponding first bumps respectively. Next, the under bump metallurgy layer is patterned to from a plurality of patterned under bump metallurgy layers by taking the first bumps and the second bumps as masks. Finally, a reflowing process is performed under a reflowing temperature between the first melting point and the second melting point to have the second bumps reflowed to shape into a ball or a sphere to encapsulate the first bump.

As mentioned above, the reflowing temperature of the step of reflowing the second bump to be shaped into a ball-like or the step of reflowing the second bump to be securely fixed to a substrate to form a flip-chip package is lower than the first melting point of the first bump. Accordingly, the first bump is kept as original shape and height so as to prevent the bump structure, made of the first bump and the second bump, from being collapsed and keep the gap between the chip and the substrate unchanged. In such a manner, the mechanical reliability will be enhanced. Besides, specifically, the first bump and the second bump are made of a material of solder. Thus, the coefficient of thermal expansion of the first bump and the second bump are substantially the same and prevent the change of the working temperature from affecting the join strength between the first bump and the second bump.

It is to be understood that both the foregoing general description and the following detailed description are exemplary, and are intended to provide further explanation of the invention as claimed.

### BRIEF DESCRIPTION OF THE DRAWINGS

The invention will become more fully understood from the detailed description given herein below illustrations only, and thus are not limitative of the present invention, and wherein:

FIG. 1 illustrates a partially enlarged cross-sectional view showing the conventional bump structure of a semiconductor wafer;

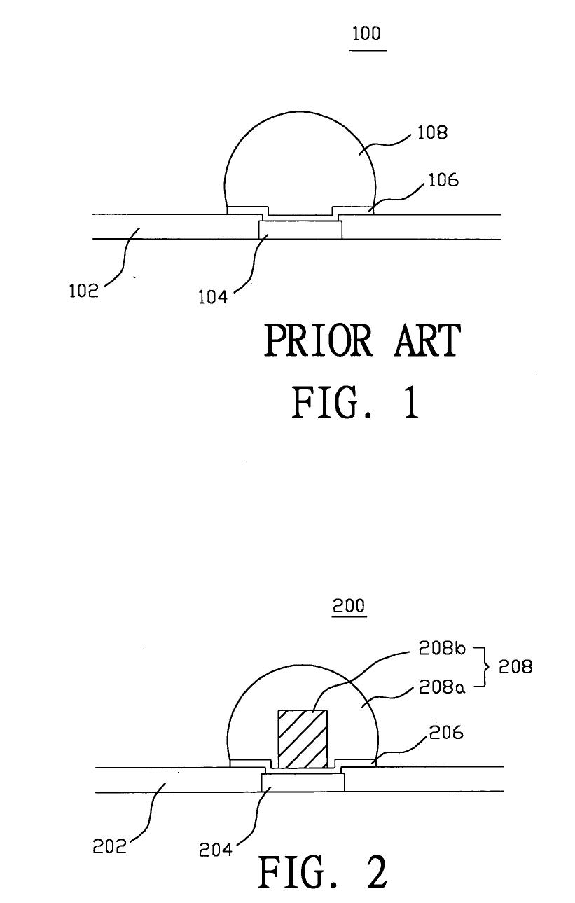

FIG. 2 illustrates a partially enlarged cross-sectional view showing the bump structure of a semiconductor wafer according to the preferred embodiment;

FIG. 3 illustrates a partially enlarged cross-sectional view showing the bump structure of a semiconductor wafer according to another preferred embodiment; and

FIGS. 4 to 8 are partially enlarged cross-sectional views showing the progression of steps for forming a bump according to the preferred embodiment of this invention as shown in FIG. 2.

### DETAILED DESCRIPTION OF THE INVENTION

The bump structure of a semiconductor and the method thereof according to the preferred embodiments of this invention will be described herein below with reference to the accompanying drawings, wherein the same reference numbers are used in the drawings and the description to refer to the same or like parts.

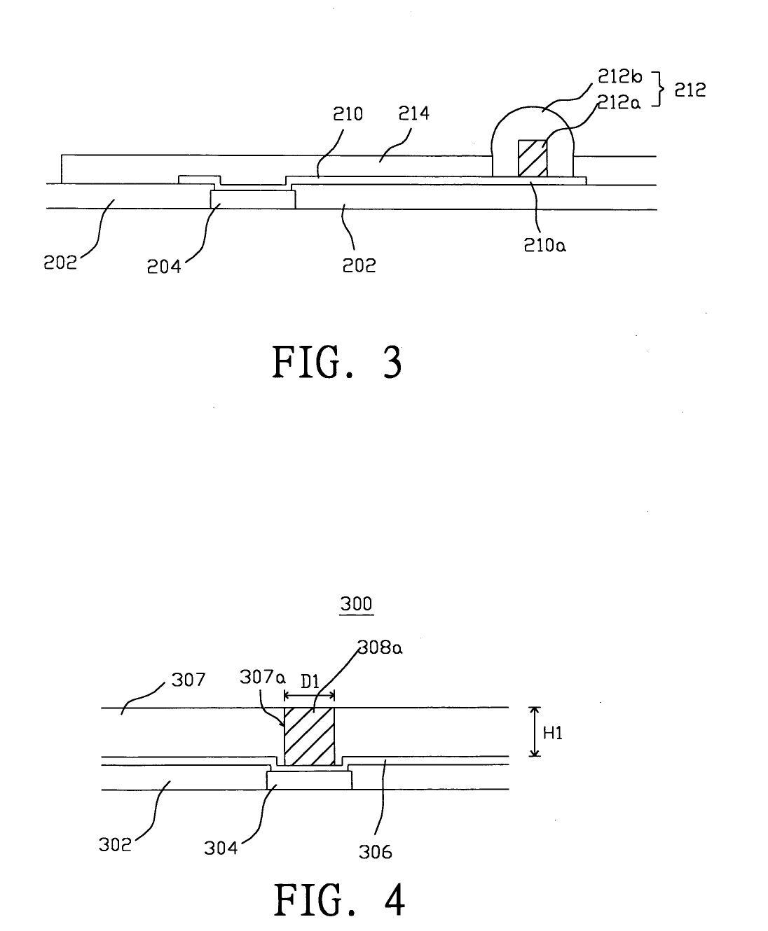

As shown in FIG. 2, there is provided a preferred embodiment of this invention. Therein, a silicon wafer 200 having a passivation layer 202, a plurality of bonding pads 204 and patterned under bump metallurgy layers 206 formed on the bonding pads 204 respectively. Therein, the passivation layer 202, which may be made of a material selected from silicon nitride, phosphosilicate glass and silicon oxide, covers the active surface of the silicon wafer 200 and exposes bonding pads 202, and the patterned under bump metallurgy layers 206 located over bonding pads 202 partially cover the passivation layer 202. Moreover, a plurality of bump structures 208 are formed on the patterned under bump metallurgy layers 206 respectively. To be noted, each bump structure 208 comprises a first bump 208aand a second bump 208b, and each second bump 208bcovers the corresponding first bump 208aand the patterned under bump metallurgy layer 206 over the bonding pad 204. Therein, the first bump 208ahas a first melting point higher than a second melting point of the second bump 208b. In addition, the first bump 208ais kept as original shape without being reflowed when the second bump 208bis reflowed to be shaped into a ball-like or a sphere and to be securely fixed to a substrate.

As mentioned above, the first bump 208aand the second bump 208bcan be made of solder. Generally speaking, the bump made of high-lead solder has a melting point about 320° C. and the bump made of eutectic solder has a melting point about 185° C. lower than that of the high-lead solder. Thus, a high-lead bump can be taken as the first bump 208aand an eutectic solder bump can be taken as the second bump 208b. Besides, the patterned under bump metallurgy layer 206 mainly comprises an adhesive layer, a barrier layer and a wetting layer. The adhesive layer is utilized to enhance the mechanical strength of the connection of the bonding pad 204 to the barrier layer, wherein the material of the adhesive layer is made of aluminum or titanium. The barrier layer is utilized to avoid the diffusion of the underlying metal, wherein the material of the barrier layer usually includes nickel-vanadium alloy, nickel-copper alloy and nickel. In addition, the wetting layer, for example a copper layer, is utilized to enhance the wettability of the solder bump with the under bump metallurgy layer. It should be noted that the patterned under bump metallurgy layer 206 is formed through the processes of placing photo-resist resist, proceeding plating or sputtering metal on the surface of the semiconductor wafer 200 and etching the metal taken as an under bump metallurgy layer.

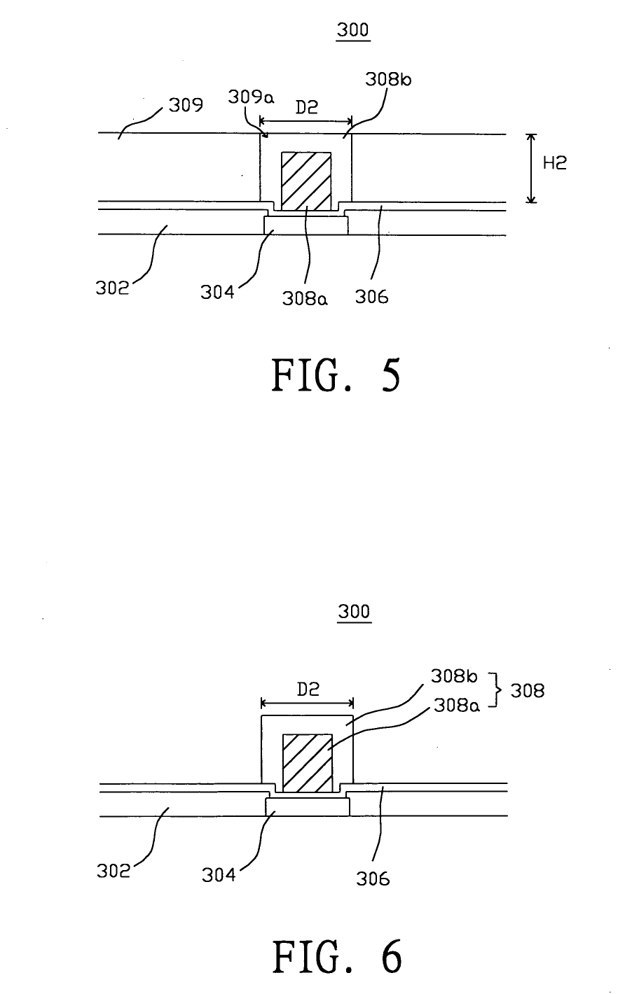

Moreover, the patterned under bump metallurgy layer 206 can be extended over the passivation layer 202 to be regarded as a redistributed layer 210 to provide a redistributed pad 210 located above the passivation layer 202. In such a manner, the bump structure as mentioned above can be disposed on the redistributed pad 210. Therein, the bump structure 212 comprises a first bump 212aand a second bump 212b as shown in FIG. 3. Besides, another dielectric layer 214 may be provided to cover the redistributed layer 210 and expose the redistributed pad 210a and the bump structure 212. To be noted, the dielectric layer can be made of a polymer material, such as Polyimide (PI) and Benzocyclobutence (BCB), to be regarded as a buffer layer to absorb additional stress and to prevent the redistributed layer 210 from being oxidized.

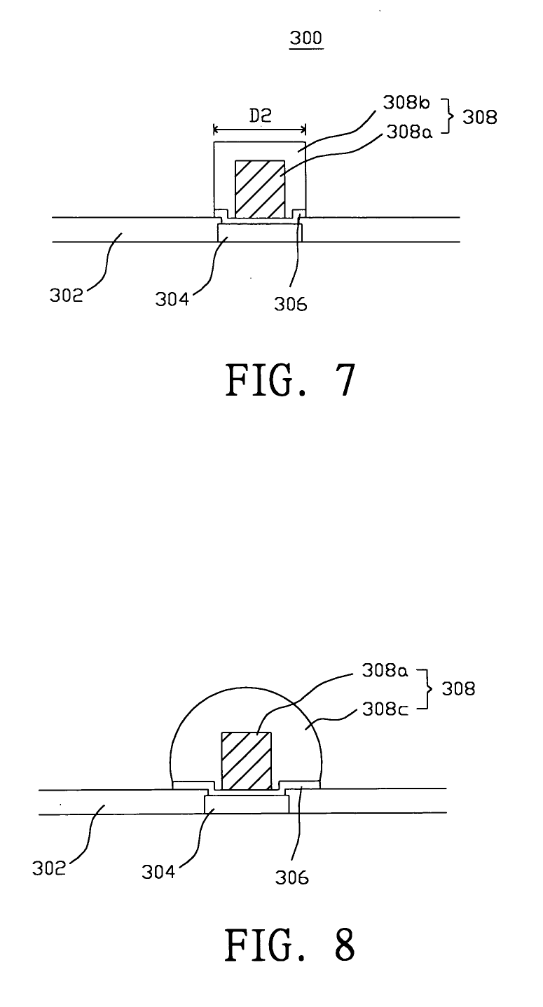

Next, referring to the partially enlarged cross-sectional views showing the progression of steps for forming a bump structure according to the above embodiment of FIG. 2 as shown from FIG. 4 to FIG. 7.

Firstly, referring to FIG. 4, a semiconductor wafer 300 is provided, wherein the semiconductor wafer 300 has a passivation layer 302 and a plurality of bonding pads 304. Therein, the passivation layer 302 is disposed above the active surface of the semiconductor wafer 300 and exposes the bonding pads 302. However, only one bonding pad 302 is shown in FIG. 4.

Next, referring to FIG. 4 again, an under bump metallurgy layer 306 is formed above the active surface of the semiconductor wafer 300 to cover the bonding pads 302. Moreover, a first mask 307 is formed above the semiconductor wafer 300 to form a plurality of first opening 307ato expose the under bump metallurgy layer 306. Therein, the first opening 307 expose the portion, located over the bonding pads 302, of the under bump metallurgy layer 306. Then, a first bump 308ais formed in the opening 307athrough filling a conductive material, such as a first solder material, by performing a screen-printing process or a plating process.

Next, referring to FIG. 5, after the first mask 307 is removed, a second mask 309 is formed above the under bump metallurgy layer 306 and expose the first bump 308aand the under bump metallurgy layer 306 which are both located over the bonding pad 304 through a second opening 309a. To be noted, the second opening 309ais larger than the first opening 307a. Namely, D2 as shown in FIG. 5 is larger than D1 as shown in FIG. 4. Moreover, the thickness of the first mask 307 is smaller than that of the second mask 309. Namely, H2 as shown in FIG. 5 is larger than H1 as shown in FIG. 4.

Next, a second bump 308bis formed through filling another conductive material, such as a second solder material, in the second opening 309aby performing another screen-printing process or another plating process. To be noted, the second bump 308bcovers the first bump 308aand a portion of the under bump metallurgy layer 306. Then, the second mask 309 is removed as shown in FIG. 6 and the bump structure 308 is taken as another mask, bump-definition mask, to pattern the under bump metallurgy layer 306 to form a patterned under bump metallurgy layer 306′ as shown in FIG. 7.

Finally, referring to FIG. 8, a reflowing process is performed to have the second bump 308bof the bump structure 308 securely fixed to the patterned under bump metallurgy layer 306′ and shaped into a ball-like shape.

As mentioned above and shown in FIG. 3, when the under bump metallurgy layer is extended over the passivation layer 202 to be regarded as a redistributed layer 210 and provide a redistributed pad 210adisposed above the passivation layer 202, said above-mentioned method shall also apply to the semiconductor wafer having redistributed layers and redistributed pads. Namely, the bump structure 212 can be disposed on the redistributed pad 210a. In addition, a dielectric layer 214 is formed to cover the redistributed layer 210 and expose the redistributed pad 210athrough spin coating and curing processes. Moreover, a dielectric film can be provided to be directly attached to the active surface of the semiconductor wafer.

As mentioned above in this invention, a second bump with a second melting point lower than that of the first bump covers the first bump, and a reflowing process is performed under a reflowing temperature between the first melting point and the second melting point to have the second bump reflowed to shape into a ball or a sphere to encapsulate the first bump. In addition, the step of reflowing the second bump to be securely fixed to a substrate to form a flip-chip package is lower than that of the first melting point of the first bump. Thus, the first bump is kept as original shape and height so as to prevent the bump structure, made of the first bump and the second bump, from being collapsed and keep the gap between the chip and the substrate. In such a manner, the mechanical reliability will be enhanced. Besides, specifically, the first bump and the second bump are made of a material of solder. Thus, the coefficient of thermal expansion of the first bump and the second bump are substantially the same and prevent the change of the temperature from affecting the join strength between the first bump and the second bump.

Although the invention has been described in considerable detail with reference to certain preferred embodiments, it will be appreciated and understood that various changes and modifications may be made without departing from the spirit and scope of the invention as defined in the appended claims.

What is claimed is:

1. A bump structure applicable to be disposed on a semiconductor wafer, wherein the semiconductor wafer has a plurality of bonding pads, a passivation layer and a plurality of patterned under bump metallurgy layers formed over the bonding pads respectively and said passivation layer is partially covered by the patterned under bump metallurgy layers, the bump structure comprising:
a first bump attached to one of the patterned under bump metallurgy layers; and
a second bump encapsulating the first bump and attached to the patterned under bump metallurgy layer.

2. The bump structure of claim 1, wherein the first bump has a first melting point above a second melting point of the second bump.

3. The bump structure of claim 1, wherein the first bump is made of solder and the second bump is made of solder.

4. The bump structure of claim 1, wherein the first bump is a high-lead solder bump.

5. The bump structure of claim 1, wherein the second bump is an eutectic solder bump.

6. The bump structure of claim 4, wherein the ration of tin to lead provided in the first bump is 5 to 95.

7. The bump structure of claim 5, wherein the ration of tin to lead provided in the second bump is 63 to 37.

8. The bump structure of claim 1, wherein the passivation layer is made of a material selected from silicon nitride, phosphosilicate glass and silicon oxide.

9. The bump structure of claim 1, wherein each of the patterned under bump metallurgy layers comprises a titanium layer, a nickel-vanadium layer and a copper layer.

10. The bump structure of claim 1, wherein each of the patterned under bump metallurgy layer is made of a material selected from titanium, titanium-tungsten alloy, aluminum, aluminum-nickel, nickel-vanadium, chromium-copper alloy, copper and nickel-vanadium.

11. The bump structure of claim 1, wherein one of the patterned under bump metallurgy layer is a redistributed layer extended over the passivaion layer.

12. The bump structure of claim 11, further comprising a dielectric layer covering the redistributed layer to expose a redistributed pad to be disposed the bump structure.

13. A method of forming a plurality of bump structures on a wafer having an active surface, wherein the wafer further includes a plurality of bonding pads formed on the active surface and a passivation layer formed on the active surface that exposes the bonding pads, the method comprising the steps of:
forming an under bump metallurgy layer above the active surface to cover the bonding pads;
disposing a first mask above the active surface to form a plurality of first openings to expose the under bump metallurgy layer;
disposing a first conductive material in the first openings to form a plurality of first bumps on the under bump metallurgy layer;
removing the first mask;
disposing a second mask above the active surface to form a plurality of second openings to expose the first bumps and the under bump metallurgy layer below the first bumps;
disposing a second conductive material in the second openings to form a plurality of second bumps to cover the first bumps and the under bump metallurgy layer located below the second bumps respectively; and
removing the second mask.

14. The method of claim 13, further comprising the step of patterning the under bump metallurgy layer by taking the first bumps and the second bumps as a bump-definition masks to form a plurality of patterned under bump metallurgy layers.

15. The method of claim 13, wherein the first openings expose the under bump metallurgy layer located over the bonding pads.

16. The method of claim 13, wherein the second openings expose the under bump metallurgy layer located over the bonding pads.

17. The method of claim 13, wherein each of said first openings is smaller than each of said second openings in size.

18. The method of claim 13, wherein the first bump has a first melting point above a second melting point of the second bump.

19. The method of claim 13, further comprising a reflowing process to have the second bump shaped into a ball-like shape and securely attached to the under bump metallurgy.

20. The method of claim 19, wherein the second melting point of the second bump is between the first melting point and a temperature for performing the reflowing process.

21. The method of claim 13, wherein the first bump is formed by the method of plating.

22. The method of claim 13, wherein the second bump is formed by the method of screen-printing.

23. The method of claim 14, wherein the patterned under bump metallurgy layers comprise a redistributed layer extended over the passivaion layer.

24. The method of claim 23, further comprising the step of disposing a dielectric layer covering the redistributed layer to expose a redistributed pad to be disposed the bump structure before the step of disposing a first mask above the active surface of the semiconductor wafer.
